(19) United States
(12) Patent Application Publication
(10) Pub. No.: US 2021/0349524 A1
(43) Pub. Date: Nov. 11, 2021

(54) SYSTEM FOR PERFORMING VIRTUAL LABORATORY AND EXPLORATORY EXPERIMENTS

(71) Applicant: Obshhestvo s ogranichennoj otvetstvennostyu "Vizeks Info", Moscow (RU)

(72) Inventors: Victor Osadchiy, Moscow (RU); Oleg Finoshin, Moscow (RU)

(21) Appl. No.: 17/379,779

(22) Filed: Jul. 19, 2021

Related U.S. Application Data
(63) Continuation of application No. PCT/RU2020/050396, filed on Dec. 25, 2020.

(30) Foreign Application Priority Data
Dec. 30, 2019 (RU) 2019145332

(51) Int. Cl. G06F 3/01; G09B 23/00; G06T 19/20; G06T 19/00

(52) U.S. Cl. CPC G06F 3/011; G06T 19/006; G06T 19/20; G09B 23/00

(57) ABSTRACT

The invention refers to a virtual laboratory and research experiment system, which includes: a virtual space object parameter setting module corresponding to real-world objects, made with the ability to set the parameters of virtual space objects. The technical result achieved by the proposed invention lies in increasing the efficiency of virtual laboratory and research experiments.

### CROSS REFERENCE TO RELATED APPLICATIONS

The present application claims priority to Russian Patent Application No. 2019145332, filed on Dec. 30, 2019, entitled “System for performing virtual laboratory and exploratory experiments”, and is a continuation of PCT/RU2020/050396, filed on Dec. 25, 2020, entitled “System for conducting virtual laboratory and research experiments,” each of which is incorporated by reference herein in its entirety.

### BACKGROUND

Currently, there is a great necessity for conducting various laboratory and research experiments aimed, inter alia, at supporting, disproving or confirming various theories and hypotheses, while the experiments can differ in their objectives and scope.

The cost of laboratory and research experiments for multiple, especially complex, experiments is quite high, since they require expensive equipment, different consumables, etc.

Virtualization of such laboratory and research experiments is one of the solutions for experiments cost reduction. Thus, real-world objects, as well as possible interactions between them (their parts, etc.), with the environment, etc., can be transferred to the virtual space, for example, by creating models (2D, 3D) using hardware and software tools available at the present time or invented later. Thus, for example, three-dimensional (3D) models can be used as virtual space objects; they can vary from simple objects, such as a flask, retort, metal bar, spring, etc. to complex objects, such as various equipment, for example, spectrometers, calorimeters, etc. The specified objects transferred to the virtual space (virtualized) are subject to various applicable laws that are currently known or new laws, that can be added to such a virtual space. For example, the physical process of a chemical reaction can be defined by the components (substances, elements) of the reaction, the parameters of the components concerned, the chemical and physical laws of the real world, in particular, set in the format of formulae in virtual space.

Thus, the current state of the art requires the creation of systems for virtualization, in particular, the complete (or partial) transfer of experiments to the virtual space created by the corresponding hardware. For example, the whole experiment or its part can be carried out in a virtual space. The results of such experiments in virtual space may completely coincide with the results of experiments in the real world or may be similar to a certain confidence sufficient to state the reproducibility of the experimental results in the real world and in the virtual space (world).

### SUMMARY OF THE INVENTION

The technical result achieved by the proposed invention comprises an increase in the efficiency of conducting virtual laboratory and research experiments.

According to one of the implementation option, it is proposed to implement a system for conducting virtual laboratory and research experiments, which includes: virtual space object parameter setting module corresponding to real world objects, made with the ability to set parameters of virtual space objects, and the specified parameters include at least the physical, chemical and/or biological properties of the virtual space object corresponding to at least the physical, chemical and/or biological properties of the real world object, however, the virtual space object parameters include at least one set of invariable parameters and at least one set of variable parameters of virtual space objects, while the set of invariable parameters includes at least the object type, points in the triangular grid of the object in which there is at least one interaction zone of such an object, the types of interactions related to the points of interactions allowed for each type of object, and set of invariable parameters includes, at least, the object name, estimated parameters of the object, variable physical parameters of the object, where the object interaction zone is set in advance and when approaching another object, subject to possible interaction, the simulation of interaction with the object or between objects is carried out according to the specified interaction parameters, moreover, the interaction zone can be selected automatically depending on the type of object, subject to interaction, or the user can select one of the available interaction zones; module for development and addition of virtual space objects, designed to create virtual space objects in the virtual space based on the specified parameters and to add the developed virtual space objects to the virtual workspace, which is a part of the virtual space, where virtual space objects are placed and handled by the user, and in which the interaction between virtual space objects can be simulated in accordance with the specified interaction parameters; interaction parameters setting module for virtual space objects, made with the ability to set interaction parameters for virtual space objects using at least one set of control actions combined into control digital entities formed for a specific type of virtual space object, where the interaction parameters can be set by interaction algorithms of at least one virtual space object with at least one more virtual space object using the physical and chemical laws of object interaction defined by the corresponding formulae in the format of digital entities, where the algorithms are determined by the knowledge area, corresponding to the virtual space; module for virtual space objects control and interaction between virtual space objects, made with the possibility of virtual space objects control by the user and their movement in the virtual space with the use of data input devices for interaction between virtual space objects with the possibility of choosing the type of interaction; virtual space object interaction simulation module, designed with the possibility of physically correct object interactions between each other and processing the results of interaction between virtual environment objects, depending on the parameters of virtual space objects, parameters of virtual space object interaction, developed in the format of digital entities in the virtual space, and made with the possibility to control the laboratory or research work simulation process in time, as well as with the possibility to record the state of the laboratory or research work simulation process in order to save it and then restore it from the saved point in time; virtual environment objects presentation module, virtual environment objects interaction and virtual space objects interaction results, made with the ability to visualize virtual space objects to the user, virtual environment objects interaction and virtual environment objects interaction results in the format of digital entities; data storage module designed to store virtual space object types, invariable object parameters, and points specified in the object's triangular grid, where the interaction zone is located, the types of interactions related to the interaction points that are allowed for each type of object through pre-defined interaction scenario, the names of objects, the individual design parameters of objects that can be changed, and the individual physical parameters of objects that can be changed, the state of the laboratory or research work simulation process and made with the ability to transfer the stored data to at least one of the object parameters adjustment modules, object interaction parameters, object control, object interaction simulation with the restoration of the interaction process from the saved point in time.

The system also contains a commenting module, which is designed for adding comments by the user and for presenting comments to users in one of the private implementation options, and the content of comments is related to events in the virtual space and virtual objects.

### BRIEF DESCRIPTION OF THE DRAWINGS

FIG. 1 demonstrates an approximate version of the object card;

FIG. 2 demonstrates an approximate version of the “Transfusion” control card;

FIG. 3 demonstrates an approximate version of the “Environment” control card.

FIG. 4 demonstrates an approximate version of the matrix appearance for three isomers of C5H12 composition, where their molecular graphs are depicted, and the vertices are numbered in random order;

FIG. 5 demonstrates an approximate version of the present invention;

FIG. 6 demonstrates an example of a general-purpose computer system,

### DETAILED DESCRIPTION

The objects and features of the present invention, as well as the methods for achieving these objects and features, will become clear by reference to the approximate embodiments. However, this invention is not limited to the approximate embodiments disclosed below, it can be implemented in various ways. The substance given in the description is nothing more than specific details provided to assist the technician in an exhaustive understanding of the invention, and the present invention is defined only to the extent of the attached formula.

The terms “module”, “component”, “element” and the similar ones used in this description refer to computer entities that may be hardware/equipment (for example, device, tool, apparatus, hardware, component part of the device, for example, processor, microprocessor, integrated circuit, printed circuit board, including electronic printed circuit board, breadboard, motherboard, etc., microcomputer, and so on), as well as software (for example, executable program code, compiled application, software module, part of software or program code, and so on) and/or microprogram (in particular, firmware).

For example, any component may serve as a process, running on a processor (by a processor), an object, executable code, program code, file, program/application, function, method, (software) library, subroutine, co-routine, and/or computing device (for example, a microcomputer or computer), or a combination of software or hardware components.

This invention applies to educational and research systems, including software and hardware, and includes a virtual environment for different laboratory and research experiments on subjects (academic disciplines), including those included in the Federal State Educational Standards.

The combination of software and hardware makes it possible (for users, in particular, learners, trainees, students, etc.) to test hypotheses, to experiment, to investigate, to confirm the reality of physical laws, to expand the range of manipulations with objects, etc.

The described invention makes it possible for (users) to control the time inside the experiment, slowing it down or speeding it up, in particular, to comfortably observe ultra-fast events or, on the contrary, to accelerate ultra-long ones—for example, the growth of a plant.

In order to conduct various laboratory and research experiments in a virtual environment, the software and hardware enable interaction with the following virtual objects: workspace (3D Table, scene, desktop); laboratory or research objects that include a list of objects and objects from the list; camera (virtual), simulation, comments.

The workspace (3D Table, scene, desktop) is used for placement and manipulation of virtual physical objects, where virtual physical objects are computer (digital) representations of physical entities (in particular, objects) developed in the virtual space in the format of digital virtual entities. Thus, for example, virtual physical objects can be developed using the parameters (characteristics) of objects in the physical (real) world. For example, for such a physical object as a wooden bar, can be used such parameters as length, width, height, material of the bar, etc., as well as environmental parameters, for example, the parameters of the environment in which this physical object (real world object) is located (or placed), for example, temperature, and can also be set physical laws applicable to physical objects, the materials from which they are made, as well as the effects on such a physical object. Or, for example, it is possible to specify the components (substances, elements) of the reaction, the parameters of the participating components, chemical, physical and other known laws of the real world, in particular, determined as formulae in the virtual space.

In a particular case, the workspace can be a plane created and displayed in a virtual space, on which including within a limited area movement can be carried out using a (virtual) camera, and items (objects) from the list of objects (in particular, libraries) can be placed, and interaction with comments can be carried out (comment, edit, view, etc.).

Laboratory or research work objects:
a list of objects, which is a digital entity that provides the ability to store and select objects, including for their visualization (in order to be read by the user) and use in the process of implementing the present invention, for example, in the process of modeling reactions, interactions, etc.;
objects from the list of objects (on the desktop) that can be interacted with, as described in the present invention.

Laboratory or research objects are elements (in a particular case, the main elements) intended for laboratory or research work. The user can create objects in the scene, interact with them, and observe their interaction in simulation mode.

Objects in the scene, in particular, three-dimensional objects (3D objects) in the scene, including objects from the list placed in the scene, can be combined (for example, with each other), connected to at least one other object (in particular, attached to other objects), filled with substances, etc., according to their parameters, in particular, properties.

The specified objects can be, for example, of the following types:
electrical elements;
containers—for substances placement;
measuring devices—for recording (registration) of the parameters of objects (environment, etc.), in particular, removing indicators from objects;
source of the substance—for filling containers with substances (liquid and gaseous);
solid bodies—metals, ice;
biological objects—organized extracellular particles (viruses), bacterial cells, fungal, plant, animal, and human tissues, enzymes and enzyme components, biogenic nucleic acid molecules, lectins, cytokinins, primary and secondary metabolites;
chemical objects—“pure substance”, chemical compound, mixture, solution;
historical entities—countries, borders, cities, armies, governors, etc.

Objects in a scene can belong to several types simultaneously, for example,

“measuring device” and “solid body” (can be a measuring device and a solid body at the same time).

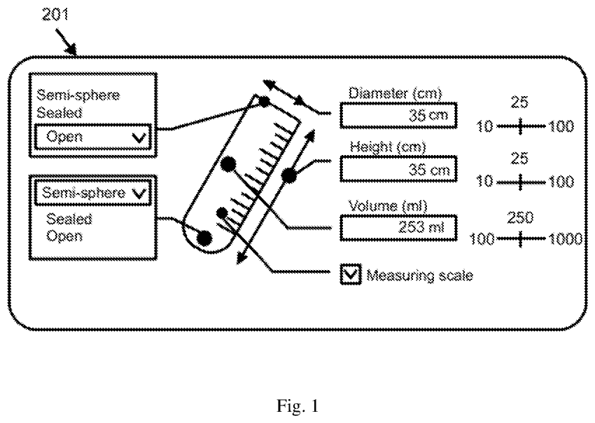

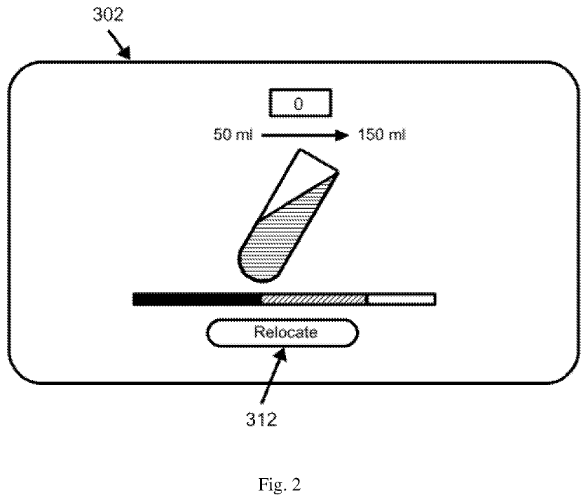

Each object has its own parameters (properties), in particular, for such objects, their own parameters can be configured:
all editable properties are displayed in the object card, as shown in FIG. 1;
objects have their place on the work area, in particular, on the table, where one or another object can be placed or where other objects cannot be placed, including until this space is available or an object of a certain type cannot be placed in such a place, etc.;
objects have a pre-defined interaction zone, when approaching another object (if you bring an object to it), subject to interaction, then the interaction can be simulated according to the specified interaction parameters (including formulae, algorithms, etc.), and the interaction can be visualized (visually displayed to the user). Thus, for example, during the approach of the pressure gauge to the flask, the flask neck can be highlighted visually (for example, the flask neck is highlighted), which visualizes the possibility of lowering the pressure gauge in the flask neck area, in particular, for the purpose of installing (attaching) the pressure gauge to the flask, according to the specified parameters of the possibility of objects connection (in particular, combining). For example, a pressure gauge can be adjusted to attach to other objects, the list (types) of which can be specified in the database, for example, in the form of a table, and for such objects to which other objects can be attached (for example, a pressure gauge), the objects (types of objects) with which such objects can be combined should also be specified in the database. Furthermore, the areas (zones) of interaction of such objects with other objects can be defined for objects, (for example, the neck of a flask), which can be used to establish connections between objects and can be used to visualize possible ways of objects connection;
objects can have multiple interaction zones, particularly in cases where different interactions are possible. So, in case of possibility of different interactions with the objects, the zone that corresponds to the object with which the interaction is carried out is activated, for example:
“Placement” zone—if the item is a container, an object;
“Connection” zone—if the object is a part, an electrical element;
“Clamping” zone—if the object is a container, object, or small measuring device. The clip can be opened by default. The clip can be closed if an object is placed in it. The clip can be opened or closed via the interface (user interface);
“Transfusion” zone—if the object is a container, the source of the substance, and the editable properties can be displayed in the transfusion card, as shown in FIG. 2.

The specified objects shall be stored in a data storage, for example, in a database. For example, a database can store basic object names, predefined (designated) object names, a set(s) of invariable parameters, or a set(s) of variable parameters, for example, in the format of database fields.

The basic names of objects, in particular, 3D objects, can be, for example, resistor, capacitor, beaker, tripod, etc.

Pre-defined object names can be, for example, a 20 kΩ resistor, etc.

The set(s) of invariable parameters can include object types (in particular, 3D objects); individual invariable table object parameters, for example, in xml notation; points specified in the triangular grid of the object where the interaction zone is located, for example, in xml notation; interaction types associated with the interaction points allowed for each object type, for example, in xml notation, through predefined interaction scenario. The object type can be, for example, a resistor, a capacitor, a beaker, a tripod, etc. Individual invariable parameters of an object can be, for example, the overall dimensions in the scene, the type and density of the material (glass, metal, etc.), pre-set unchangeable physical parameters, etc.

The set(s) of variable parameters can include user-defined object names; individual variable calculated parameters of objects, for example, in xml notation; individual variable physical parameters of objects, for example, in xml notation. The mentioned user-defined object names can be, for example, “My 25 kΩ resistor”. For example, the resistance of a resistor, the capacitance of a capacitor, the volume of a beaker, and another parameter can serve as individual variable design parameters of an object. Individual variable physical parameters of objects can be, for example, the electrical resistivity of the resistor material, the temperature coefficient of resistance, the heat capacity, etc.

FIG. 1 illustrates an approximate version of the object card.

As it is shown in FIG. 1, the object card 201 makes it possible to change parameters such as the user-defined name of the object, for example, “My 25 kΩ resistor”, “My 50 kΩ resistor”, etc. At the same time, the object card 201 makes it possible to change individual variable parameters of the object, such as the resistance of the resistor, the capacitance of the capacitor, the volume of the beaker, the size of the beaker, the presence or absence of a measuring scale, etc. The object card 201 also makes it possible to change individual changeable physical parameters of the object, for example, the electrical resistivity of the resistor material, the temperature coefficient of resistance, the heat capacity, J/mol·K, etc.

A set of control actions combined into control cards can be used for interaction between objects (3D objects)—for example, “Transfusion”, “Burning”, “Cooling”, “Environment”, etc.

An approximate version of the control card is given in FIG. 2, in particular, an approximate version of the control card “Transfusion”.

The card given in FIG. 2 makes it possible to move a liquid or gas from one container to another, or to fill the container from any source. So, for example, the said action can be performed by relocation (including initiating such an action) using at least one graphical user interface element, for example, the “Relocate” graphical user interface element 312.

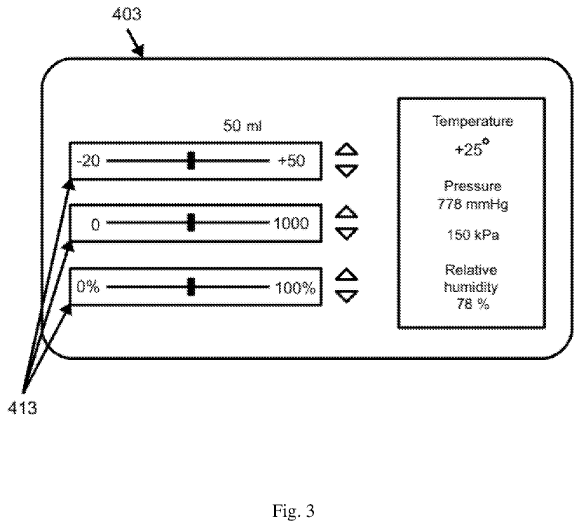

FIG. 3 illustrates an approximate version of the control card, in particular, an approximate version of the “Environment” control card.

The environment is an object involved in the simulation described in the present invention and completely fills the laboratory (in particular, the scene), and in the special case, by default, fills all created containers (located on the scene). Opened containers can be used for heat exchange with the environment.

The environment card 403 shown in FIG. 3 makes it possible to configure environmental parameters, for example, temperature, pressure, relative humidity, etc., using the appropriate interface elements, in particular, the elements of the graphical user interface (413).

Comments are a digital (computer) entity, providing the opportunity to read and leave comments in the project, linking (reference) the content with events or virtual physical objects.

Virtual (software) camera for moving the user's view in a virtual environment, in particular, in the workspace (operating space, etc.). The virtual camera can be located in a virtual (software) scene. For example, a virtual scene can include a virtual camera and virtual (software) content. A virtual (three-dimensional) scene can include software objects, in particular, geometric objects (flat and three-dimensional), which (for example, one of the surfaces of which) can contain content, and the user can control the camera to move the camera in virtual space, or the camera can be controlled automatically by means of the described invention. For example, a scene can contain a plane on the surface of which a digital entity (in particular, content) can be displayed, for example, text in the form of a list. The camera can be placed, for example, inside a sphere or cube to display content placed on the inner surface of such a sphere or cube. A virtual camera (software camera, virtual 3D camera) can determine which part of the scene (in particular, the content) to display to the user at a given moment. The virtual camera is controlled by the user (by means of the described system), for example, using at least one input device (data), for example, using a joystick, keyboard, “Mouse” manipulator, etc. and can be oriented in the scene depending on the specified algorithm and/or user actions and determines the visible area of such space. In a particular case, the area of visible space (the visible area of space) is a pyramid, for example, a truncated pyramid. It can be determined by the angles of the field of view. The virtual camera can be positioned at any point in the scene to receive the image placed in the scene, and the content placed on the scene object will be visible. The visualized generated image from the virtual camera can be displayed by means of the described data visualization (display) tool, for example, on a monitor (display), for observing the objects of the scene by the user.

Thus, the image can be generated by placing a virtual camera in the scene and rendering the bitmap image from this camera on the monitor.

Simulation is a digital (computer) entity that is a physically correct interaction of objects with each other (depending on the laws formed in virtual space, for example, in the format of formulae, dependencies, etc., based on the laws of the real world).

Simulation can be considered as the management of the laboratory or research work process over time. In the special case, the simulation in the scene is continuous. In a particular case, the user can control the simulation speed (set the simulation speed). It is also possible to save the system (in particular, the system in the scene), in particular, the simulation, the scene, the state of objects, etc., for example, by the user and/or by means of the described system and return to the saved state, including at a certain point in time.

Modeling of chemical, physical (and other well-known) processes carried out using the functionality implemented by the described system, including using algorithms (computer, mathematical), mathematical formulae, etc., describing the behavior of physical and chemical objects in user-defined parameters, in particular, in the “Environment” object. See the card given in FIG. 3.

Each subject (for example, those included in the Federal State Educational Standards) is pre-defined with objects (3D objects) for various laboratory and research experiments, and for each pre-defined object. The parameters of such objects and their interaction are pre-defined, including by means of a set of algorithms for interaction with other pre-defined objects. The parameters used, including sets of algorithms, are determined by the area of knowledge for which a virtual environment is created in order to carry out various laboratory and research experiments.

For example, it is possible to set and use settings, parameters, etc., including algorithms that describe the physical properties of bodies in various aggregate states based on their molecular structure, for conducting virtual “Physics” experiments in the “Molecular Physics” section.

In a particular case, for conducting virtual experiments in “Physics”, section “Electrodynamics”, algorithms describing the operation of electrical circuits are used.

In a particular case, an algorithm is defined as mathematical formulae describing physical or chemical laws that can be used in a virtual environment to conduct various laboratory and research experiments, according to certain subjects (for example, those included in the Federal State Educational Standards).

In a particular case, for conducting virtual experiments on the subject “Physics”, the section “Molecular Physics”, the following formulae are used to calculate the algorithms:
“Amount of substance”,
“The basic equation of the kinetic molecular theory of an ideal gas”,
“Mean square speed of the molecules of an ideal gas”,
“The average kinetic energy of the molecules of a monatomic gas”,
“The pressure of the ideal gas”, “Boyle-Mariotte's law”,
“Charles Law”,
“Gay-Lussac's law”,
“Mendeleev's-Clapeyron equation”,
“Gas state unified law (Clapeyron's equation)”,
“Dalton's Law”,
“Internal energy of an ideal monatomic gas”,
“Elementary work performed by a gas”,
“First law of Thermodynamics”,
“Ideal gas heat capacity”.

In a particular case, all objects (3D objects) in virtual experiments in the discipline, “Molecular Physics” section, can be divided into four aggregate states: Solid, Liquid, Gaseous, and Plasma. In this case, the Solids are divided into Crystalline and Amorphous.

Each type and kind of object is defined, identified, and assigned certain formulae that describe its behavior and interaction with other types and types of objects.

In a particular case, the following types of interactions (processes)—isothermal, isochoric, isobaric, and adiabatic processes—can be used in virtual experiments in Physics (“Molecular Physics” section) to simplify calculations.

Simulation of biological processes (mathematical and logical —mathematical descriptions of the structure, connections, and patterns of functioning of living systems) is carried out, including being constructed (formed), using, inter alia, on the basis of previously described experimental data, formalized describing a hypothesis, theory, or previously discovered pattern of a particular biological phenomenon and, in a particular case, does not require further experimental verification.

In a particular case, the following modeling logic is used to conduct virtual experiments in Chemistry (“Inorganic Chemistry”):
it is established (in particular, it is calculated) whether the flow of a particular chemical reaction is energetically favorable. For example, can it flow spontaneously without the supply of energy from the outside? The answer to this question can be found in the thermodynamic function—Gibbs energy (Gibbs potential);
the calculation of the rate and mechanism of chemical reactions is carried out using the formulae of chemical kinetics. So, for example, there are thermodynamically favorable chemical reactions, but they proceed very slowly kinetically. An example of such a reaction is the reaction of graphite burning in oxygen to form carbon dioxide;
the rate of a chemical reaction is calculated as a function of temperature and of the catalyst, taking into account the vibrational reactions, where the rate of a chemical reaction is the change in the amount of a substance per unit of time in a unit of reaction space, and vibrational reactions are reactions characterized by fluctuations in the concentrations of certain intermediate compounds and, accordingly, the rates of transformation;
the molar masses of the substances are calculated, and then the total mass and volume of the resulting substance are calculated using the reaction equation for each chemical substance;

moreover, it is taken into account that many chemical reactions are reversible, i.e. they can occur both in the forward and reverse directions, and at some (equilibrium) concentrations of the starting substances and reaction products, the rates of the forward and reverse reactions become equal, and chemical equilibrium or phase equilibrium occurs.

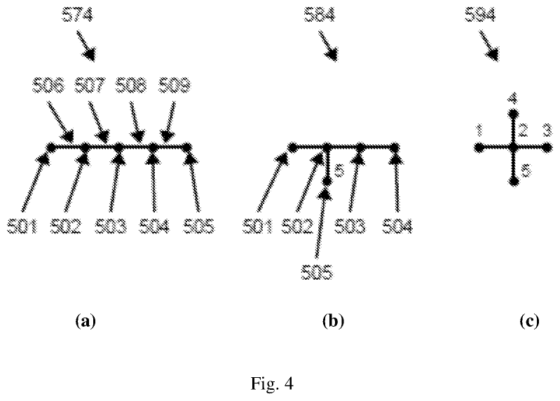

In a particular case, the following modeling logic is used to conduct virtual experiments in Chemistry (“Organic Chemistry”):
graphs are objects, in particular, mathematical objects that can be characterized by numbers and express the structure of molecules by numbers that are related to the structure of molecular graphs (so-called “topological indices”). The topological index allows you to establish connection between its values and the properties of substances, and then use this connection to calculate the mass and volume of the resulting substance;
methods for calculating topological indices shall meet the following requirements:
   each molecule has its own individual index;
   molecules with similar properties have similar indices;
the basis for the construction of many indices is the concept of “distance matrix” (the so-called matrix, the elements of which show the number of edges separating the corresponding vertices of the molecular graph). An approximate version of the appearance of the matrix for three isomers of the composition C5H12 is shown in FIG. 4, where their molecular graphs are depicted, and the vertices are numbered in any order);
the diagonal elements of the distance matrix for hydrocarbons are 0. In the first column (574, FIG. 4a) vertex 1 (501) is connected to vertex 2 (502) by one edge (506), so matrix element d12=1; vertex 1 (501) is connected to vertex 3 (503) by two edges (506, 507), so matrix element d13=2; vertex 1 (501) is connected to vertex 4 (504) by three edges (506, 507, 508), therefore, the matrix element d14=3; vertex 1 (501) is connected to vertex 5 by four edges (506, 507, 508, 509), therefore, the element of the matrix d15=4 and so on for the remaining elements for such a matrix. Similarly, the matrix elements are calculated for the second graph (584, FIG. 4b) and the third graph (594, FIG. 4c). Thus, the complete distance matrices for the three graphs can be written as follows (the matrix on the left is for the first graph, the matrix in the center is for the second graph, and the matrix on the right is for the third graph):

$$( \begin{matrix}0 & 1 & 2 & 3 & 4 \\ 1 & 0 & 1 & 2 & 3 \\ 2 & 1 & 0 & 1 & 2 \\ 3 & 2 & 1 & 0 & 1 \\ 4 & 3 & 2 & 1 & 0\end{matrix} ) ( \begin{matrix}0 & 1 & 2 & 3 & 2 \\ 1 & 0 & 1 & 2 & 1 \\ 2 & 1 & 0 & 1 & 2 \\ 3 & 2 & 1 & 0 & 3 \\ 2 & 1 & 2 & 3 & 0\end{matrix} ) ( \begin{matrix}0 & 1 & 2 & 2 & 2 \\ 1 & 0 & 1 & 1 & 1 \\ 2 & 1 & 0 & 2 & 2 \\ 2 & 1 & 2 & 0 & 2 \\ 2 & 1 & 2 & 2 & 0\end{matrix} )$$

the distance between the vertices does not depend on the order of their enumeration, so the distance matrices are symmetric with respect to the diagonal;
another type of index is the Randich index, which is based not on the distances between vertices, but on the number of nearest neighbors for each vertex. This index is calculated using the formula:

$$χ ( G ) = {\sum }_{All \\ edges} \frac{1}{\sqrt{{v}_{i} {v}_{j}}}$$

where vi is the degree of the i-st vertex, that is, the number of edges extending from it. For other graphs, the Randich index is:

$$χ ( {G}_{1} ) = \frac{1}{\sqrt{{v}_{1} {v}_{2}}} + \frac{1}{\sqrt{{v}_{2} {v}_{3}}} + \frac{1}{\sqrt{{v}_{3} {v}_{4}}} + \frac{1}{\sqrt{{v}_{4} {v}_{5}}} = \frac{1}{\sqrt{2}} + \frac{1}{2} + \frac{1}{2} + \frac{1}{\sqrt{2}} = 1 + \sqrt{2} = 2.414$$

$$χ ( {G}_{2} ) = \frac{1}{\sqrt{{v}_{1} {v}_{2}}} + \frac{1}{\sqrt{{v}_{2} {v}_{3}}} + \frac{1}{\sqrt{{v}_{3} {v}_{4}}} + \frac{1}{\sqrt{{v}_{2} {v}_{5}}} = \frac{1}{\sqrt{3}} + \frac{1}{\sqrt{6}} + \frac{1}{\sqrt{2}} + \frac{1}{\sqrt{3}} = 2.270$$

$$χ ( {G}_{3} ) = \frac{1}{\sqrt{{v}_{1} {v}_{2}}} + \frac{1}{\sqrt{{v}_{2} {v}_{3}}} + \frac{1}{\sqrt{{v}_{2} {v}_{4}}} + \frac{1}{\sqrt{{v}_{2} {v}_{5}}} = 4 \frac{1}{\sqrt{4}} = 2.000$$

This index decreases with increasing degree of branching of the carbon skeleton (used to describe the physical properties of alkanes). Alkanes do not contain any “features”—double and triple bonds or atoms of other elements that can radically change the properties of the substance, the addition of one oxygen atom turns the inert gaseous ethane C2H6 into liquid ethanol C2H5OH.
in topological indices of molecules more complex than alkanes, the presence of multiple bonds and heteroatoms can be taken into account (in particular, by assigning certain numerical coefficients—“weights”- to the vertices and edges of graphs);
the use of topological indices to characterize the biological activity of drugs can significantly save time and money (a large number of substances that, according to the results of the calculation of the indices, obviously do not have the required properties shall be discarded).

In order to simulate the interaction between scientific disciplines, for example, modeling the behavior of objects in an electrical circuit and simultaneously heating these objects, algorithms are used to describe the behavior of objects in various chemical and physical processes.

Such, for example, if the object (3D object) is set changeable physical parameters of the object (such as, for example, the electrical resistivity of the resistor material, the temperature coefficient of resistance, the heat capacity, etc.), for example, in the database of the 3D object, the fields of the changeable physical parameters of the 3D object in xml notation are filled in, then when the object is simultaneously exposed to various electrical, thermal or inorganic chemical reactions in the experiment (virtual experiment in the scene), the algorithmic calculation of their joint interaction can be carried out by means of the described system, using the following rules:
the thermochemical reaction equations of several inorganic chemical objects interaction in a virtual experiment are calculated using Hess' law, provided that the thermal effect of the reaction does not depend on the intermediate scenes, but is determined only by the initial and final state of the system, and provided that the pressure or volume remains unchanged throughout the process;
the resistivity of materials under heating increases as a result of an increase in the speed of movement of atoms in the conductor material with increasing temperature.

The resistivity of electrolytes and coal when heated, on the contrary, decreases, since these materials, in addition to increasing the speed of movement of atoms and molecules, increase the number of free electrons and ions per unit volume.

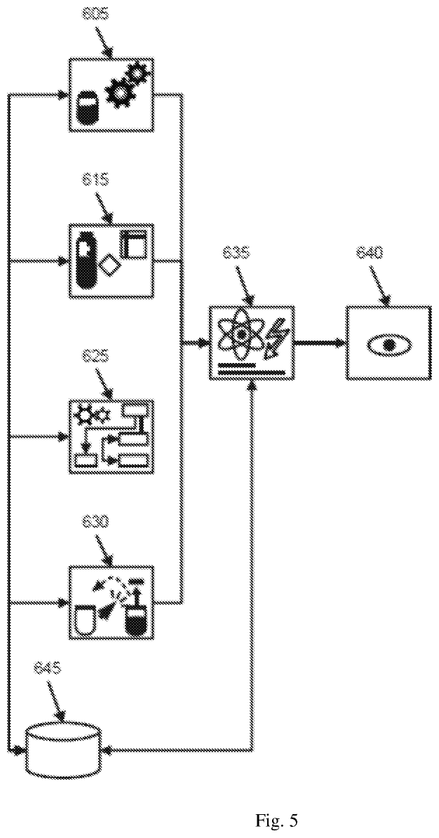

FIG. 5 shows an approximate version of the proposed system.

As shown in FIG. 5, the proposed system includes a module for setting the parameters of virtual space objects 605 corresponding to real-world objects. The virtual space object parameter setting module 605 allows you to set the parameters of virtual space objects, and the specified parameters can include physical, biological, chemical and other known properties of the virtual space object corresponding to the physical, biological, chemical and other known properties of the real-world object. The parameters of virtual space objects can include a set(s) of invariable parameters and a set(s) of variable parameters of virtual space objects, and the sets of invariable parameters can include the type of object, points in the triangular grid of the object in which there is at least one interaction zone of such an object, the types of interactions associated with the interaction points allowed for each type of object. A set of invariable parameters can include the name of the object, the calculated parameters of the object, the physical parameters of the object that can be changed, where the zone of interaction of the object can be set in advance (for example, by the user) and when approaching which other object with which interaction is possible, the interaction with the object or between objects is simulated according to the specified interaction parameters. The interaction area can be selected automatically by means of the described system, for example, depending on the type of object with which the interaction is carried out, or one of the available interaction zones can be selected by the user, and the possible zone for selection can be accentuated (for example, highlighted) by means of the described system, for example, the module for presenting objects of the virtual environment, interaction of objects of the virtual environment and the results of interaction of objects of the virtual space 640.

FIG. 5 also contains a module for creating and adding virtual space objects 615. The module for creation and addition of virtual space objects 615 makes it possible to create virtual space objects in the virtual space based on the specified parameters and add the created virtual space objects to the virtual workspace, which is part of the virtual space, where virtual space objects are placed and manipulated by the user, and in which interaction between virtual space objects is simulated according to the specified interaction parameters.

The described system also contains a module for setting parameters for the interaction of virtual space objects 625. The module for setting parameters for the interaction of virtual space objects 625 makes it possible to set parameters for the interaction of virtual space objects using at least one set of control actions combined into control digital entities formed for a certain type of virtual space object, where the interaction parameters can be set by algorithms for the interaction of at least one virtual space object with at least one other virtual space object using the physical and chemical laws of the interaction of objects defined by the corresponding formulae in the format of digital entities, where the algorithms are determined by the domain of knowledge corresponding to the virtual space.

FIG. 5 also contains a module for managing virtual space objects and interaction between virtual space objects 630. The virtual space object management and interaction module 630 makes it possible for the user to control virtual space objects, for example, to move them in a virtual space using data input devices (for example, a keyboard, virtual reality glasses, a joystick, etc.) in order to implement interaction between objects of the virtual space with the possibility to choose the type of interaction.

The described system also contains a module for simulating the interaction of virtual space objects 635. The module for simulating the interaction of virtual space objects 635 makes it possible to perform physically correct interactions of objects with each other and process the results of interaction of virtual environment objects depending on the parameters of virtual space objects, parameters of interaction of virtual space objects formed in the format of digital entities in the virtual space. At the same time, the module for simulating the interaction of virtual space objects 635 makes it possible to control the process of simulating laboratory or research work in time, as well as to record the state of the process of simulating laboratory or research work in order to save it and then restore it from the saved point in time.

FIG. 5 also contains a module for presenting objects of the virtual environment, the interaction of the virtual environment objects, and the results of the virtual space objects interaction 640. The module for presenting objects of the virtual environment, the virtual environment objects interaction and the results of the virtual space objects interaction 640 performs visualization of the virtual space objects, the virtual environment objects interaction and the results of the virtual environment objects interaction in the format of digital entities. For example, the module for presenting virtual environment objects, interaction of virtual environment objects, and the results of interaction of virtual space objects 640 can display virtual space objects on the display of a computing device.

FIG. 5 also contains a data storage module 645. The data storage module 645 allows you to store the types of objects in the virtual space, the invariable parameters of objects, the points specified in the triangular grid of the object where the interaction zone is located, the types of interactions associated with the interaction points allowed for each type of object through pre-defined interaction scenarios, the names of objects, individual variable calculated parameters of objects, individual variable physical parameters of objects, the states of the simulation process of laboratory or research work. At the same time, the data storage module 645 transfers the stored data to at least one of the modules for adjusting object parameters, object interaction parameters, object management, object interaction simulation, and restoring the interaction process from the saved point in time.

The described system can also contain a commenting module, made with the ability to add comments by the user and with the ability to present comments to users, and the content of comments is related to events in the virtual space and virtual objects.

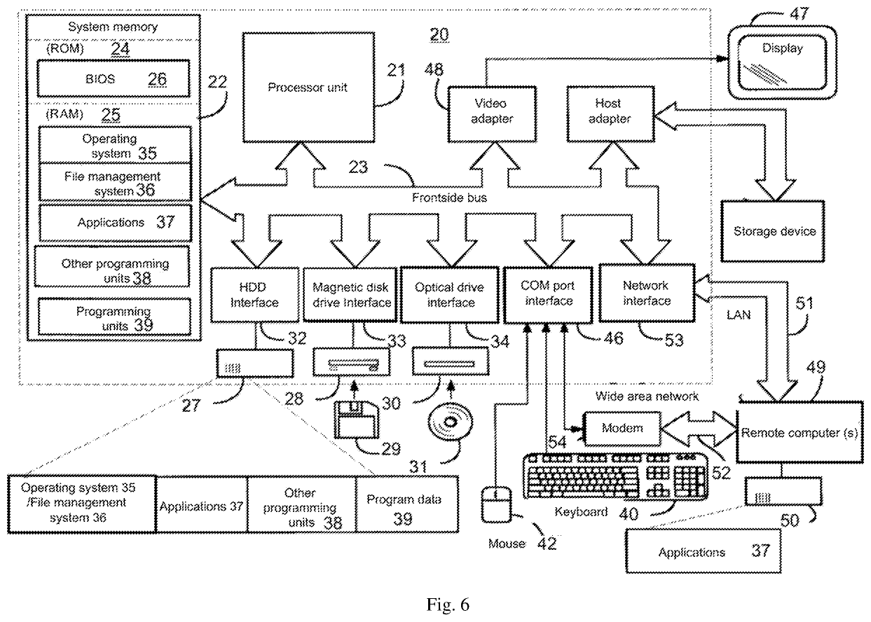

FIG. 6 shows an example of a general-purpose computer system that includes a multi-purpose computing device in the form of a computer 20 or a server, including a processor 21, system memory 22, and a system bus 23 that connects various system components, including system memory, to the processor 21.

The system bus 23 can be any of various types of bus structures, including a memory bus or memory controller, a peripheral bus, and a local bus using any of a variety of bus architectures. The system memory includes a read-only memory (ROM) 24 and a random access memory device (RAM) 25. The ROM 24 stores the basic input/output system 26 (BIOS), consisting of basic routines that help exchange information between elements inside the computer 20, for example, during startup.

The computer 20 may also include a hard disk drive 27 for reading from and writing to a hard disk, not shown, a magnetic disk drive 28 for reading from or writing to a removable magnetic disk 29, and an optical disk drive 30 for reading from or writing to a removable optical disk 31 such as a CD, digital video disk, and other optical media. The hard disk drive 27, the magnetic disk drive 28, and the optical disk drive 30 are connected to the system bus 23 via the hard disk drive interface 32, the magnetic disk drive interface 33, and the optical disk drive interface 34, respectively. Storage devices and their corresponding computer-readable means provide non-volatile storage of computer-readable instructions, data structures, program modules, and other computer data 20.

Although the typical configuration described here uses a hard disk, a removable magnetic disk 29, and a removable optical disk 31, the specialist will take into account that in a typical operating environment, other types of computer-readable media may also be used that can store data that is accessible by a computer, such as magnetic cassettes, flash memory cards, digital video disks, Bernoulli cartridges, random access memory (RAM), read-only memory (ROM), etc.

Various software modules, including the operating system 35, can be stored on a hard disk, magnetic disk 29, optical disk 31, ROM 24, or RAM 25. The computer 20 includes a file system 36 associated with or included in the operating system 35, one or more software applications 37, other software modules 38, and program data 39. The user can enter commands and information into the computer 20 using input devices such as the keyboard 40 and the pointing device 42. Other input devices (not presented) may include a microphone, a joystick, a gamepad, a satellite dish, a scanner, or any other device.

These and other input devices are connected to the processor 21 often via a serial port interface 46, which is connected to the system bus, but can be connected via other interfaces, such as a parallel port, a game port, or a universal serial bus (USB). A display 47 or other type of visual display device is also connected to the system bus 23 via an interface, such as a video adapter 48. In addition to the display 47, personal computers typically include other output peripherals (not shown), such as speakers and printers.

The computer 20 can operate in a network environment through logical connections to one or more remote computers 49. The remote computer (or computers) 49 may be another computer, server, router, network PC, peer-to-peer device, or other single network node, and usually includes most or all of the elements described above in relation to the computer 20, although only the storage device 50 is shown. Logical connections include a local area network (LAN) 51 and a wide area network (WAN) 52. Such network environments are usually common in institutions, corporate computer networks, and the Internet.

A computer 20 used in a LAN network environment connects to a local network 51 via a network interface or adapter 53. A computer 20 used in a WAN network environment typically uses a modem 54 or other means to establish communication with a global computer network 52, such as the Internet.

The modem 54, which can be internal or external, is connected to the system bus 23 via the serial port interface 46. In a network environment, the software modules or parts of them described in relation to the computer 20 may be stored on a remote storage device. It should be taken into account that the network connections shown are typical, and other means can be used to establish communication between computers.

In conclusion, it should be noted that the information provided in the description are examples that do not limit the scope of the present invention as defined by the formula. It becomes clear to a specialist in this field that there may be other embodiments of the present invention that are consistent with the essence and scope of the present invention.

We claim:

1. Comprehensive system for virtual laboratory and research experiments, which includes:
virtual space object parameter setting module corresponding to real world objects, made with the ability to set parameters of virtual space objects, and the specified parameters include at least physical, chemical and/or biological properties of the virtual space object corresponding to at least physical, chemical and/or biological properties of the real world object, the virtual space object parameters include at least one set of invariable parameters and at least one set of variable parameters of virtual space objects, wherein the set of invariable parameters includes at least the object type, points in the triangular grid of the object in which there is at least one interaction zone of such an object, the types of interactions related to the points of interactions allowed for each type of object, and set of variable parameters includes, at least, the object name, estimated parameters of the object, variable physical parameters of the object, where the object interaction zone is set in advance and when approaching another object, subject to possible interaction, the simulation of interaction with the object or between objects is carried out according to the specified interaction parameters, moreover, the interaction zone is selected automatically depending on the type of object, subject to interaction, or the user can select one of the available interaction zones;
module for development and addition of virtual space objects, designed to create virtual space objects in the virtual space based on the specified parameters and to add the developed virtual space objects to the virtual workspace, which is a part of the virtual space, wherein virtual space objects are placed and handled by the user, and in which the interaction between virtual space objects can be simulated in accordance with the specified interaction parameters;
interaction parameters setting module for virtual space objects, made with the possibility to set interaction parameters for virtual space objects using at least one set of control actions combined into control digital entities formed for a specific type of virtual space object, wherein the interaction parameters are set by interaction algorithms of at least one virtual space object with at least one more virtual space object using the physical and chemical laws of object interaction defined by the corresponding formulae in the format of digital entities, where the algorithms are determined by the knowledge area, corresponding to the virtual space;
module for virtual space objects control and interaction between virtual space objects, made with the possibility of virtual space objects control by the user and their movement in the virtual space with the use of data input devices for interaction between virtual space objects with the possibility of choosing the type of interaction;
virtual space object interaction simulation module, made with the possibility of physically correct object interactions between each other and processing the results of interaction between virtual environment objects, depending on the parameters of virtual space objects, parameters of virtual space object interaction, developed in the format of digital entities in the virtual space, and made with the possibility to control the laboratory or research work simulation process in time, as well as with the possibility to record the state of the laboratory or research work simulation process in order to save it and then restore it from the saved point in time;
virtual environment objects presentation, virtual environment objects interaction and virtual space objects interaction results module, made with the ability to visualize virtual space objects to the user, virtual environment objects interaction and virtual environment objects interaction results in the format of digital entities;
data storage module designed to store virtual space object types, invariable object parameters, points specified in the object's triangular grid, where the interaction zone is located, the types of interactions related to the interaction points that are allowed for each type of object through pre-defined interaction scenarios, the names of objects, the individual variable calculated parameters of objects, the individual variable physical parameters of objects, the state of the laboratory or research work simulation process and made with the ability to transfer the stored data to at least one of modules for correcting the object parameters, object interaction parameters, object control, objects interaction simulation with the restoration of the interaction process from the saved point in time.

2. The system, according to claim 1, additionally containing a commenting module made with the ability to add comments by the user and for presenting comments to users, wherein the content of comments is related to events in the virtual space and with virtual objects.
